(19) United States
(12) Patent Application Publication
(10) Pub. No.: US 2008/0311762 A1
(43) Pub. Date: Dec. 18, 2008

(54) Semiconductor device surface roughness reduction

(76) Inventor: Mark Doczy, Meridian, ID (US)

Correspondence Address: CAVEN & AGHEVLI;c/o INTELLEVATE, LLC, P.O. BOX 52050, MINNEAPOLIS, MN, 55402, US

(21) Appl. No.: 11/820,088

(22) Filed: Jun. 18, 2007

(51) Int. Cl. H01L 21/00; G21K 5/00

(52) U.S. Cl. 438/795; 250/492.2; 257/E21.001

(57) ABSTRACT

Methods and apparatus relating to surface roughness reduction are described. In one embodiment, a particle beam may be directed onto the surface roughness of a semiconductor device to reduce the roughness. Other embodiments are also disclosed.

### BACKGROUND

The present disclosure generally relates to the field of electronics. More particularly, an embodiment of the invention relates to reduction of roughness on the surface of a semiconductor device.

The magnitude of sidewall roughness in semiconductor devices has not been scaling downward as quickly as feature dimensions have. As a result, the magnitude of this roughness is becoming a bigger component of the critical dimension, leading to variability in transistor off-state leakages and in line and contact resistances.

Some current implementations may use photoresist and lithography optimization to reduce roughness. But, such approaches can become more difficult as devices become smaller.

### BRIEF DESCRIPTION OF THE DRAWINGS

The detailed description is provided with reference to the accompanying figures. In the figures, the left-most digit(s) of a reference number identifies the figure in which the reference number first appears. The use of the same reference numbers in different figures indicates similar or identical items.

FIGS. 1a and 1b illustrate side views of relative roughness of semiconductor surfaces after an erosion process and after adding energy to the surface, respectively, in accordance with some embodiments.

FIG. 2 illustrates a side view schematic of the resulting energy transfer of various energy incidence angles on a surface, according to some embodiments.

FIG. 3 illustrates a side view schematic of energy deposition onto a surface via energetic ions and/or neutrals, in accordance with some embodiments.

FIG. 4 illustrates a side view schematic of an azimuthal orientation of grazing incidence relative to ripple direction of a semiconductor surface, in accordance with an embodiment.

FIG. 5 illustrates a perspective view of ion direction, in accordance with one embodiment.

FIG. 6 illustrates a cross sectional view of a film stack, in accordance with one embodiment.

### DETAILED DESCRIPTION

In the following description, numerous specific details are set forth in order to provide a thorough understanding of various embodiments. However, various embodiments of the invention may be practiced without the specific details. In other instances, well-known methods, procedures, components, and circuits have not been described in detail so as not to obscure the particular embodiments of the invention. Further, various aspects of embodiments of the invention may be performed using various means, such as integrated semiconductor circuits (“hardware”), computer-readable instructions organized into one or more programs (“software”), or some combination of hardware and software.

Some of the embodiments discussed herein may enable reduction of surface roughness on semiconductor devices, such as roughness on sidewalls of lines, trenches, vias, etc. In an embodiment, a low-mass, super-thermal atomic bombardment may be utilized for edge roughness reduction. In one embodiment, the roughness achieved by photoresist optimization may be further reduced by techniques discussed herein. Some of the embodiments may be applied subsequent to an etch process. For example, in one embodiment, roughness of roughened surfaces may be reduced by using a molecular particle source applied after resist development or final etch. Moreover, the molecular particle source may be applied intermittently, e.g., in a pulsing scheme, during the etch process.

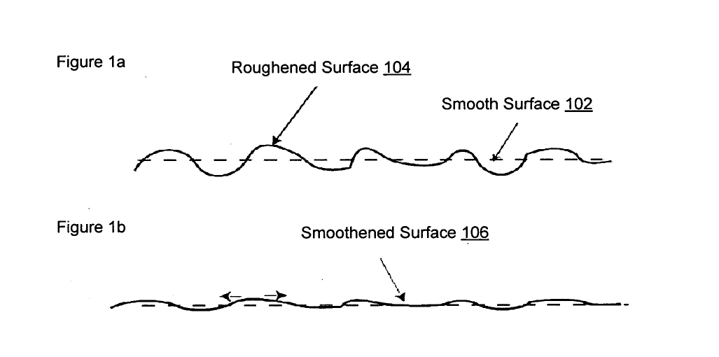

FIGS. 1a and 1b illustrate side views of relative roughness of semiconductor surfaces after an erosion process (e.g., etch or photoresist develop which may roughen a surface) and after adding energy to the surface, respectively, in accordance with some embodiments. As shown in FIG. 1a, a smooth surface 102 (shown as a dashed line in FIGS. 1a and 1b), when compared with a roughened surface 104, may provide a thermodynamically more stable surface, but solid material does not generally migrate to this state easily. Although a rough surface (e.g., surface 104) may not be thermodynamically favorable, the lack of surface mobility may prevent a smooth surface. In one embodiment, adding energy to a surface such as the roughened surface 104 (e.g., without removing material in one embodiment) may allow surface mobility and/or diffusion to increase, resulting in surface adjustment toward a relatively smoother surface (such as the smoothened surface 106), e.g., due to reduced viscosity which may allow surface tension to stretch out the roughness, such as shown in FIG. 1b.

In an embodiment, a moderate energy (e.g., less than or equal to about 1000 eV), low mass (e.g., less than about 12 amu) ionic/atomic/molecular flux onto a roughened surface (e.g., surface 104) may smooth that surface considerably (e.g., resulting in surface 106). In one embodiment, the energy may be sufficient to increase surface viscosity (e.g., about 1-1000 eV) with mass low enough not to transfer momentum and induce sputtering reaction. Hydrogen and Helium may be the utilized species from atomic mass standpoint in some embodiments. Due to lack of chemical reactivity, Helium may be used in more implementations. Neon is also possible in some implementations. The high energy atomic particles may be generated through a variety of techniques such as plasma, ion beam, or energetic neutral beam.

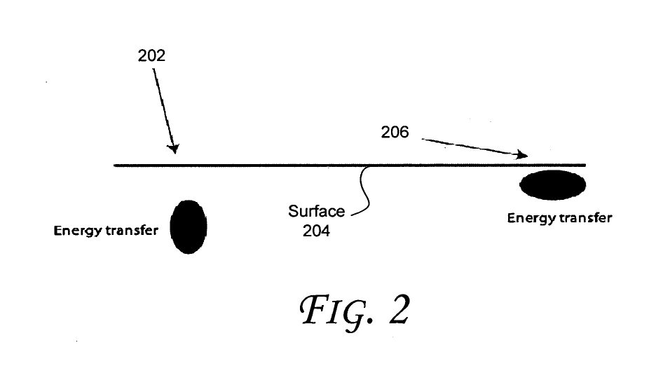

FIG. 2 illustrates a side view schematic of the resulting energy transfer of various energy incidence angles on a surface, according to some embodiments. As shown in FIG. 2, a near normal incidence 202 may deposit energy below a semiconductor surface 204 (e.g., which may be the same or a similar surface as those discussed herein, e.g., with reference to other figures) and a grazing incidence 206 may deposit energy at or near the surface 204. Hence, a grazing incidence 206 may provide a more efficient energy transfer in one embodiment.

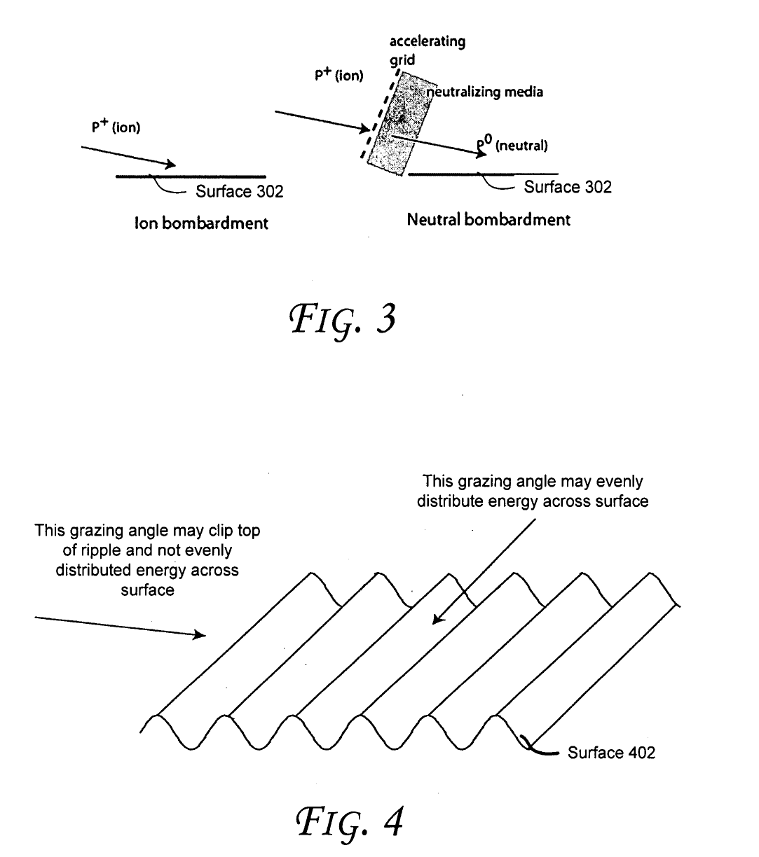

FIG. 3 illustrates a side view schematic of energy deposition onto a surface via energetic ions and/or neutrals, in accordance with some embodiments. More specifically, the left portion of FIG. 3 illustrates that energetic ions may be deposited onto a surface 302 (e.g., which may be the same or a similar surface as those discussed herein, e.g., with reference to other figures). Alternatively, the right portion of FIG. 3 illustrates that energetic ions may be passed through an accelerating grid and neutralizing media (e.g., to generate neutrals) prior to the opposition on the surface 302.

FIG. 4 illustrates a side view schematic of an azimuthal orientation of grazing incidence relative to ripple direction of a semiconductor surface, in accordance with an embodiment. With edge roughness, the azimuthal orientation of the energy grazing incidence relative to ripple direction may determine how evenly surface energy is distributed onto a surface 402 (e.g., which may be the same or a similar surface as those discussed herein, e.g., with reference to other figures). In one embodiment, to maximize smoothing effect, energy may be more evenly distributed via grazing angles that are in incident on the surface 402 in the same or similar direction of surface ripples, such as shown in FIG. 4.

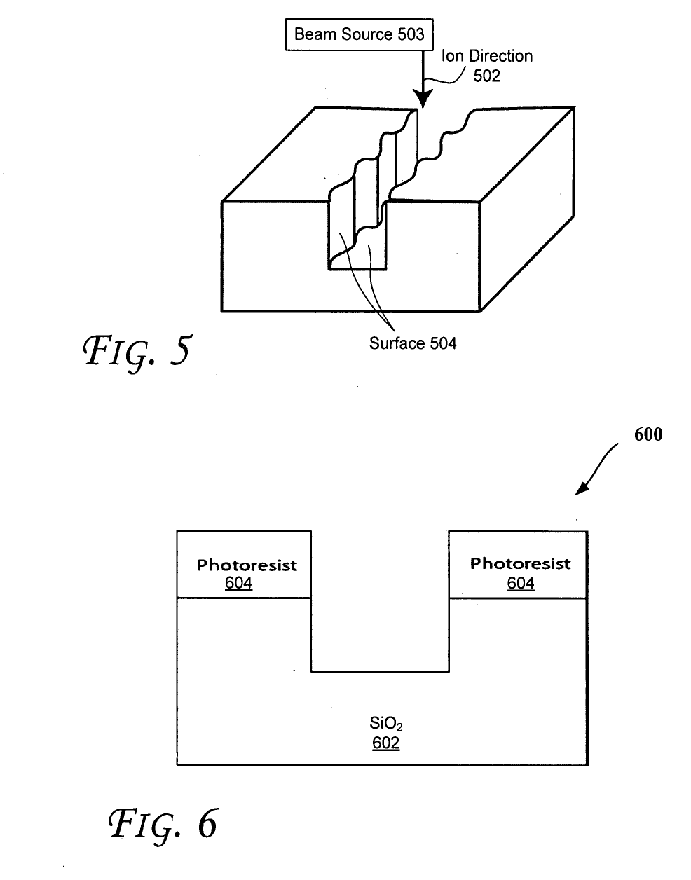

FIG. 5 illustrates a perspective view of ion direction, in accordance with one embodiment. More specifically, ion direction 502 (e.g., from a beam source 503 such as a plasma etcher discussed herein) may be used to minimize roughness of surface 504, e.g., where light ion such as Helium (or other elements such as those discussed with reference to a FIG. 1) is used. The surface 504 may be the same or a similar surface as those discussed herein, e.g., with reference to other figures.

FIG. 6 illustrates a cross sectional view of a film stack 600, in accordance with one embodiment. The techniques discussed herein for reduction of roughness may be applied to any film stack such as the film stack 600 shown in FIG. 6. The film stack 600 may include a silicon oxide structure 602, e.g., with photoresist 604 present on the structure 602.

In some embodiments, localized energy may be introduced onto surface of patterned structures fabricated during semiconductor manufacturing. The localized energy added to the surface may increase surface diffusion and lower surface viscosity such that a more thermodynamically stable surface results (such as the smooth surface 106 of FIG. 1b). The energy may be added to the surface by accelerating atomic or molecular sized particles incident on the surface at a near grazing incidence (e.g., as shown in FIG. 2). The particles may be accelerated by a plasma radio frequency (RF) sheath or by use of an ion gun, in some embodiments. The accelerated ions may or may not be neutralized by the time they reach the material surface of interest (see, e.g., FIG. 3).

In an embodiment, the momentum transfer from the impacting particles to the atomic particles in the material may be sufficiently low so that ejection of atoms from the surface does not occur, a phenomenon known as “sputtering.” Sputtering might induce surface roughening effect, over and above the surface smoothing effects of increased surface diffusion. This may be best achieved with very low mass particles, such as Hydrogen or Helium. Material may also be removed by chemical etching (which is to be avoided in an embodiment), so Helium may be used over Hydrogen due to Helium being inert. The grazing incidence may provide localization of bombarding energy at the surface, see, e.g., FIG. 2. On an initially rough surface, proper angling of the molecular species may help equalize the energy received by all portions of the surface regardless of surface curvature (see, e.g., FIG. 4). The proper angling of the molecular species may be achieved by plasma etch equipment (see, e.g., FIG. 5).

In some embodiments, the introduction of energetic He ions accelerated by 100 W of RF bias may smoothen the photoresist and SiO₂ layers. In an embodiment, He ion treatment may be performed after structure is etched. In another embodiment, the smoothing process may be performed applied intermittently, e.g., in a pulsing scheme, during the etch process as structure is being etched.

Furthermore, in some embodiments, the beam source 503 may be one or more of a plasma beam source, an ion beam source, or an energetic neutral beam source for generating atomic particles with one or more of the following characteristics: (a) accelerating source to generate particles of sufficient energy (1-1000 eV); (b) sufficiently low mass ions (e.g., less than about 12 amu) to reduce or eliminate sputter erosion; (c) chemically un-reactive species, e.g., to reduce material removal; (d) with energy and mass below sputtering threshold of material; (e) with energy and mass sufficient to drive surface diffusion or enhance surface viscosity; (f) no or limited chemical or physical etching of material; (g) species at near grazing incidence of surface, e.g., to focus energy at the surface; and/or (h) species perpendicular to a wave vector associated with the surface roughness.

Reference in the specification to “one embodiment” or “an embodiment” means that a particular feature, structure, and/or characteristic described in connection with the embodiment may be included in at least an implementation. The appearances of the phrase “in one embodiment” in various places in the specification may or may not be all referring to the same embodiment.

Also, in the description and claims, the terms “coupled” and “connected,” along with their derivatives, may be used. In some embodiments of the invention, “connected” may be used to indicate that two or more elements are in direct physical or electrical contact with each other. “Coupled” may mean that two or more elements are in direct physical or electrical contact. However, “coupled” may also mean that two or more elements may not be in direct contact with each other, but may still cooperate or interact with each other. Additionally, for the purposes of this disclosure, reference to “logic” shall mean either hardware, software, or some combination thereof.

Thus, although embodiments of the invention have been described in language specific to structural features and/or methodological acts, it is to be understood that claimed subject matter may not be limited to the specific features or acts described. Rather, the specific features and acts are disclosed as sample forms of implementing the claimed subject matter.

What is claimed is:

1. An apparatus comprising:
a semiconductor device having roughness on at least one surface of the semiconductor device; and
a beam source to generate atomic particles incident on the at least one surface of the semiconductor device,
wherein the atomic particles incident on the roughness cause the roughness to be smoothened.

2. The apparatus of claim 1, wherein the beam source is to generate the atomic particles with an energy level of about 1000 eV or less.

3. The apparatus of claim 1, wherein the beam source comprise one or more of a plasma beam source, an ion beam source, or an energetic neutral beam source.

4. The apparatus of claim 1, wherein the beam source is to generate the atomic particles with a mass of less than about 12 amu.

5. The apparatus of claim 1, wherein the atomic particles are chemically un-reactive.

6. The apparatus of claim 1, wherein the beam source is to generate the atomic particles to increase surface viscosity of the surface.

7. The apparatus of claim 1, wherein the beam source is to generate the atomic particles at near grazing incidence of the surface.

8. The apparatus of claim 1, wherein the beam source is to generate the atomic particles to focus energy at the surface substantially perpendicular to a wave vector associated with the roughness.

9. The apparatus of claim 1, wherein the beam source is to generate the atomic particles from one or more of Helium, Hydrogen, or Neon.

10. The apparatus of claim 1, wherein the atomic particles comprise energetic neutrals, wherein an accelerating grid and a neutralizing media coupled between the beam source and the surface are to convert energetic ions generated by the beam source to the neutrals.

11. A method comprising:
directing an energetic particle beam onto at least a surface of a semiconductor device; and
reducing a roughness of the surface in response to the beam incident on the roughness.

12. The method of claim 11, further comprising generating the energetic particle beam.

13. The method of claim 12, wherein generating the beam comprises generating a beam with an energy level of about 1000 eV or less.

14. The method of claim 12, wherein generating the beam comprises generating a beam with one or more of: a plasma beam source, an ion beam source, or an energetic neutral beam source.

15. The method of claim 12, wherein generating the beam comprises generating an energetic particle beam with a mass of less than about 12 amu.
